(19) United States
(12) Patent Application Publication
(10) Pub. No.: US 2002/0118643 A1
(43) Pub. Date: Aug. 29, 2002

(54) Method and system for digital communications over a fragmented channel

(76) Inventors: Ofir Shalvi, Herzlia (IL); Ariel Yagil, Ramat Hasharon (IL)

Correspondence Address: DANA L. BURTON, TEXAS INSTRUMENTS INCORPORATED, P.O. BOX 655474, MS 3999, DALLAS, TX, 75265, US

(21) Appl. No.: 09/988,722

(22) Filed: Nov. 20, 2001

Related U.S. Application Data
(60) Provisional application No. 60/249,967, filed on Nov. 20, 2000.

(51) Int. Cl. G01R 31/08

(52) U.S. Cl. 370/230; 370/237

(57) ABSTRACT

A data communication method and system are provided for communications over a channel that consists of multiple sub-channels. A data communication system is provided with a transmission channel having transmission sub-channels for transmitting and receiving data, the system comprising: a first terminal for transmission of data on one or more of a first plurality of sub-channels; a second terminal for transmission of data on one or more of a second plurality of sub-channels wherein the first plurality of sub-channels and the second plurality of sub-channels are partially overlapping such that at least one sub-channel is shared by the first terminal and the second terminal and at least one sub-channel is not shared by the first terminal and the second terminal; and a control mechanism for allocating data transmission between the sub-channels. A method of data transmission in a communication system is also provided. Other methods and systems are also provided.

### CROSS-REFERENCE TO RELATED APPLICATIONS

The following coassigned patent applications are hereby incorporated herein by reference:

| Serial No. | Filing Date | TI Case No. |
|---|---|---|
| 09/761,545 | 01/16/01 | TI-31218 |

### FIELD OF THE INVENTION

This invention generally relates to communication systems, and more specifically to systems and methods for data transmission.

### BACKGROUND OF THE INVENTION

Cable modems are being deployed today that allow high speed Internet access in the home over a cable network, often referred to as a hybrid fiber coax (HFC) cable network. The architecture of a typical cable modem used in a cable network is shown in FIG. 1. A cable modem 10 is a unit that is installed in the consumer or customer premises equipment (CPE) that may comprise a personal computer (PC) 13 or other computing device, for example. The cable modem (CM) 10 is adapted to communicate with the cable modem termination system (CMTS) that is typically located at a cable network provider's headend 12. The cable modem 10 is a modulator/demodulator that receives Internet traffic or information from a server through the headend 12 and puts it into a format recognizable by a user's PC 13, allowing a user to browse the Internet and send/receive e-mail just as they would with a conventional modem on a PC. Using a cable modem 10 over a cable network provides a much faster connection, being at least 50 times faster than a 56 K modem, for example. Only one cable modem 10 is shown in FIG. 1. However, there are generally multiple cable modems 10 connected to a given headend 12 and transmitting over sub-channels 32, 34, 36, and 38.

Cable modem 10 performs the modulation and demodulation and the operations necessary to interface with a user's PC. A cable modem 10 typically comprises a transmitter 14 for upstream modulation of a signal, usually comprised of short bursts, that is transmitted to a receiver 16 in the headend 12 that serves as an upstream demodulator. The upstream signal may comprise webpage selection or search information, for example, and may be a QPSK/16 QAM modulated signal at 3 Mbits/sec. The cable modem 10 also comprises a receiver 18 for downstream demodulation of signals received from a transmitter 20 in the headend 12 that serves as a downstream modulator. The downstream modulation/demodulation may be 64 QAM/ 256 QAM at 27-56 Mbits/s, for example. Both the cable modem 10 and headend 12 include MACs 22, 24 that control the media access control (MAC) sublayer of the communication network.

A standard for communicating data over cable is the Data Over Cable Service Interface Specification (DOCSIS), There have been several iterations thus far of DOCSIS (e.g., 1.0, 1.1 and 2.0). According to the DOCSIS 1.0 specification, in the United States, the cable downstream channel which may be capable of carrying several Gigabits of data per second is divided into 6 MHz sub-channels that are capable of carrying 30-40 Megabits of data per second each from the cable headend 12 to the Cable Modems (CM's) 10. In current DOCSIS systems 30, each user 40,42,44,46 is receiving data through a single receive channel 32,34,36,38 and sending data through a single upstream channel 32,34,36,38 as shown in FIG. 1.

### SUMMARY OF THE INVENTION

In general, and in a form of the present invention a method and system for digital communications over a fragmented channel is provided. In accordance with the present invention in one embodiment a system is provided that comprises at least one terminal that is capable of transmitting data in a plurality of sub-channels; at least one terminal that is capable of receiving data in a plurality of sub-channels; and a manager that shifts the transmitted data bits between sub-channels that can be used by both transmitting terminals and receiving terminals. Alternatively, instead of a manager as a control mechanism a distributed control system can be used to coordinate data transmission, Various embodiments for allocation of sub-channels in accordance with the present invention are disclosed herein.

An alternative method and system is also disclosed in which the terminals are rapidly hopping between sub-channels, in order to avoid usage of a congested channel. A method and system for rapid hopping that will work with common prior art systems and specifications for digital communication over CATV (such as the DOCSIS spec) is disclosed.

Other methods and systems are also disclosed.

### BRIEF DESCRIPTION OF THE DRAWINGS

Particular embodiments in accordance with the invention will now be described, by way of example only, and with reference to the accompanying drawings in which like reference signs are used to denote like parts and in which the Figures relate to the digital system of FIG. 1, unless otherwise stated, and in which:

FIG. 1 illustrates the architecture of a typical cable modem;

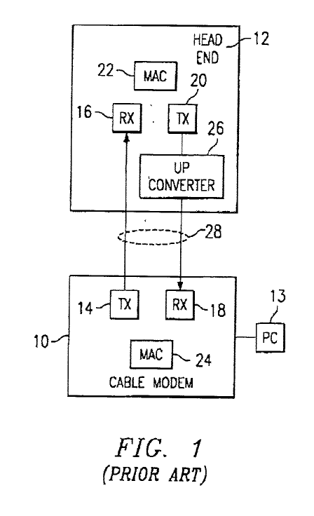

FIG. 2 illustrates a prior art approach to channel allocation;

FIG. 3 illustrates an exemplary scalable virtual channel approach to channel allocation;

FIG. 4 illustrates an exemplary spillover allocation approach to channel allocation according to an embodiment of the present invention;

FIG. 5 illustrates an exemplary staggered allocation approach to channel allocation according to an embodiment of the present invention; and

FIG. 6 illustrates an exemplary balanced allocation approach to channel allocation according to an embodiment of the present invention

Corresponding numerals and symbols in the different figures and tables refer to corresponding parts unless otherwise indicated.

### DETAILED DESCRIPTION OF EMBODIMENTS OF THE INVENTION

Although the invention finds particular application to the downstream channel in a DOCSIS system, which is described herein as an example, the intention is applicable to a wide range of communications system beyond DOCSIS downstream. For example, the invention could also be applicable to DOCSIS upstream networks, terrestrial RF (xMDS) networks, cellular and satellite networks. In the embodiments and examples described below a cable modem is often used as the exemplary terminal for transmitting and receiving. However, in other applications the terminal would be of the type appropriate for that communications system. The term “user” or “users” are also used in reference to terminals. In addition, the word “transmission” is used et broadly herein to include either transmitting data, receiving data or both.

Users needs related to length and speed of data transfer varies. Users request can be for very short (a fraction of a second), short (few seconds) or long (few minutes) periods of several Megabits per second of data per each user (e.g. for file transfer, JPEG image download, video clips, or VoD). Some of the data requests delay-sensitive (DS) (e.g. video) and some of them are delay-insensitive (DI) (e.g. file transfer). The network manager in a fragmented channel should allocate users to a sub-channel so that their overall peak demand (or at least the overall peak demand of DS requests) is lower than the nominal throughout of the sub channel, otherwise data is either delayed or lost. Therefore, the average data rate going through a channel may be significantly lower than its nominal throughput.

Advanced networks, such as some DOCSIS 1.1 networks, give priority to DS data in case of channel congestion. In other words, when the DS data is at its peak data rate, the data rate allocated to DI data is reduced, and thus DI applications are delayed. However, in the future, as video and other types of DS data become more and more popular, the amount of the DS data in the network will increase, and the duration of DS data-rate peaks in the system will be also increased. Furthermore, DS data cannot always be distinguished from DI data. Users will probably become less and less tolerant to the resulting delays of up to a few seconds in applications that are considered DI today (e.g. HTML page transfer), Therefore, there is a need for a system that can achieve high network utilization without relying on degrading the quality of service of DI applications.

Theoretically, the best solution in the sense of eliminating the degradation due to channelization of the cable would be that each CM 40,42,44,46 is capable of using all the DOCSIS sub-channels 32, 34,36,38 simultaneously. That would improve the peak to average of the throughput and will eliminate the degradation due to channelization of the cable, but it is currently very expensive and not practical.

In an embodiment provided herein a method and system are disclosed for digital communications over a fragmented channel, that is a channel that consists of multiple sub-channels wherein terminals in the system can simultaneously use only a sub-set of the sub-channels. For example, in the case of a digital communications system operating over a CATV plant according to the DOCSIS 1.0 specification, the CATV plant is a fragmented channel consisting of multiple 6 MHz sub-channels in the downstream direction, and 0.16-3.2 MHz in the upstream direction. The proposed method and system can achieve higher channel utilization than prior art systems, particularly in cases where the data rates required by the terminals vary dynamically in time.

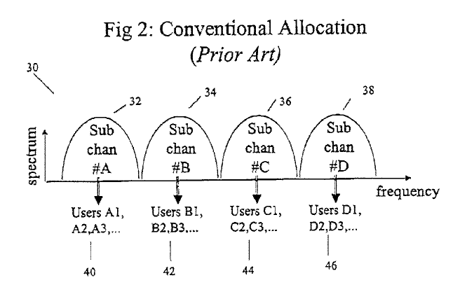

In an embodiment provided herein the conventional allocation approach of FIG. 2 is modified such that each CM 40,42,44,46 be able to hop quickly to a new channel 32,34,36,38 in case the channel that it uses becomes congested. The current DOCSIS standards may not support rapid channel changes. However, the DOCSIS specification and prior art DOCSIS systems may be modified to allow for rapid channel changes. For example, synchronization of multiple downstream channels may be done at the headend in the sense of synchronizing MAC and MPEG framing timing, FEC/interleaver framing time, and/or symbol timing, Additionally, a CM 10 may use the above synchronization approach to achieve rapid acquisition time when hopping from one channel to another. Moreover, pre-ranging of multiple downstream and upstream channels may be used to calibrate delay times, signal power, frequency offsets, equalizer values and pre-equalizer values in multiple channels. The results of the pre-ranging may then be stored in a CM 10, or in the headend 12, or in another device that is connected to the network, and the stored results may be used when hopping to a new sub-channel.

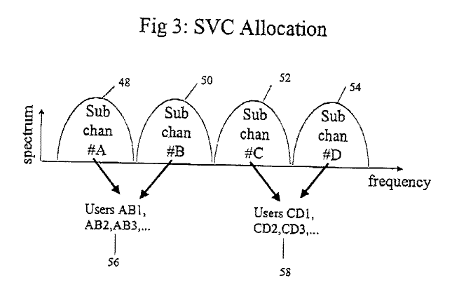

Referring to FIG. 3, an approach is disclosed, inter alia, in the above referenced related application, where each terminal 56,58 is capable of receiving in multiple 6 MHz channels 48,50,52,54 and the downstream spectrum, for example, is divided into wider virtual channels 56,58 (N times 6 MHz each, where N equals 2 in the example in FIG. 3), rather than the 6 MHz channels used today. Again, this would improve the peak to average of the throughput

In an embodiment of the present invention some (or all) terminals are able to use multiple sub channels simultaneously. We denote such terminals by the name SVC terminals (Scalable Virtual Channel). In the present invention, the sets of sub-channels used by different terminals may be partially overlapping, that is that for some pairs of terminals there are: at least one sub-channel used both terminals and at least one sub-channel used by one terminal and not by the second terminal. (For example, terminal #1 uses channels 10 and 13; while terminal #2 uses channels 13 and 14 ). In additional embodiments, allocation systems and methods are disclosed that dynamically shift data going to an SVC terminal between the different sub-channels that are being used by that SVC terminal, based on monitoring of the data load in the sub-channels in the system.

Several embodiments for the allocation systems and methods of the present invention are provided below. These embodiments are provided as examples. A person skilled in the art would understand that the present invention could be applied in other ways. In the embodiments provided, each SVC terminal is shown using two sub-channels, while the system can also contain conventional terminals that are capable of working in a single sub-channel. The same and other embodiments of the invention can be used where there are more than two sub-channels per SVC terminal and where there are no conventional terminals. In addition, the figures show a simplified version of a channel by showing only four sub-channels. Generally speaking there can be many more sub-channels with the present invention being equally applicable with the increased number of sub-channels

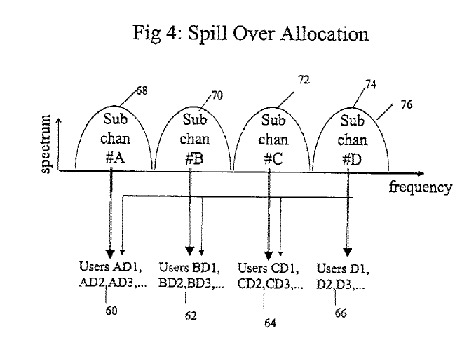

The spillover or spill-off channel allocation approach is shown in FIG. 4. Each SVC terminal 60,62,64,66 uses a regular sub-channel and a spill-off sub-channel. In this architecture all of the users in regular channels A 68, B 70, C 72, D 74 (M, M+1, M+2, . . . M+K) have one common spill-off channel 76. In FIG. 4, D is shown as both regular channel 74 and spill-off channel 76 as an example. However, the spill-off channel can also be a dedicated spill-off channel. Moreover, there may be multiple spillover channels, which may be in various configurations, such as that shown in FIG. 4 and dedicated channels as described above. Note that the non-SVC users can use only a regular sub-channel. Under this approach the benefits of the present invention are realized. However, it is probably not the optimal use of the present invention. This approach can be used in CATV system using the existing OOB (Out Of Band) channel, which is typically used in Set-top boxes as a spill over channel for items such as control and encryption keys.

Using the spillover approach for downstream transmission, the headend would, for example, follow the following procedure for each channel A 68, B 70, C 72, D 74 (M,M+1, . . . M+K):

While the channel is not congested and there are data items to transmit to non-SVC terminals transmit data items that go to non-SVC (single sub channel) terminals in the channel;

While the channel is not congested and there are data items to transmit to SVC terminals transmit data items that go to SVC terminals in the channel;

While the spill-over channel is not congested and there are data items to transmit to SVC terminals transmit data items that go to SVC terminals in the spill-over channel.

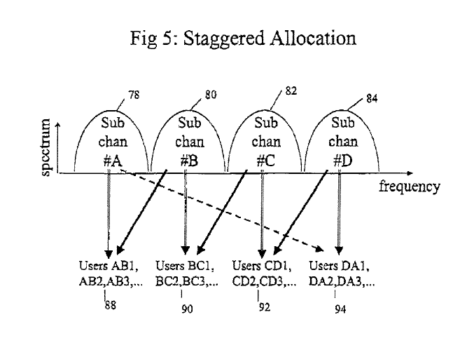

The staggered spillover channel allocation approach is shown in FIG. 5. The regular sub-channel 78,80,82,84 is sub-channel M, and the spill over channel 78,80,82,84 is sub-channel M+1. (E.g., some terminals 88,90,92,94 receive data in channels A 78 and B 80, some in channels B 80 and C 82, some in channels C 82 and D 84, and so on . . . ). As an example, the system consists of “allocators” where the M^{th} allocator decides what to do with data that can go in either sub channel M or sub channel M+1. M₀ is used to denote the number of sub-channels in the system. Following is an algorithm for the M^{th} allocator:

If M>1 then

While sub-channel M is not congested

Transmit spill over data received from sub-channel M−1

While sub-channel M is not congested

Transmit data to non-SVC terminal of channel

While the sub-channel M is not congested

Transmit data to SVC users that are tuned to sub-channels M and M+1

If M<M₀ then

Send a spill over data request to the allocation algorithm of channel M+1, consisting of all the data to SVC users that can be tuned to sub-channels M and M+1, which was not transmitted due to congestion.

In the above example, the first allocator is not receiving any spillover requests, while the M₀ allocator is not sending any spillover requests. In another embodiment, as shown in FIG. 5, the M₀ allocator can send a request to the first allocator and some SVC terminals can tune simultaneously to sub-channels A 78 (1) and D 84 (M₀).

A simulation was performed for the staggered spillover approach in a scenario where each channel can transmit up to 15 information items. The result is an improvement of 30% in throughput compared to the conventional approach. Moreover, at least when there are many sub-channels in the system, this approach is only a few percent lower in throughput from the optimal approach. The simulation is provided in the attached Appendix.

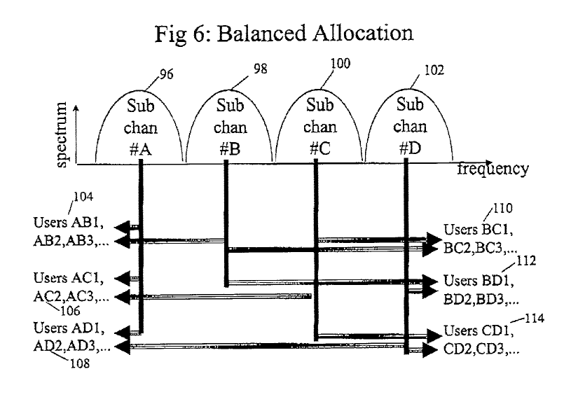

The balanced channel allocation approach is shown in FIG. 6. In this example, each terminal 104,106,108,110,112,114 uses two sub-channels 96,98,100,108 to receive data (and possibly two other sub channels to transmit data).

There are M₀! /(K!(M₀−K)!) ways to choose K sub-channels combinations out of M₀ sub-channels (that is M₀(M₀−1)/2, in case K=2). When allocating channels 96,98,100,102 to terminals 104,106,108,110,112,114 (e.g. when a new modem is registered), the system is trying to give equal data rate loads to all the M₀!/(K!(M₀−K)!) subsets of terminals that are using all of the possible combinations. Random choice of sub-channels to be allocated to each new terminal can be a useful approach in allocating channels in this scenario.

In this embodiment, each packet (or MAC frame) can be transmitted via two alternative sub-channels, according to the target (or source) CM 10. Therefore, the headend 12 has 2^{N} possibilities to allocate N packets, and it can choose the possibilities that balance between the sub-channels, and avoid frame loss.

A possible allocation algorithm that may be employed with this approach is to allocate the packets one after the other, and allocate each packet to the less occupied sub-channel from the two possible candidates. This allocation algorithm is from another art area and is more fully described in On-Line Routing Of Virtual Circuits With Applications To Load Balancing And Machine Scheduling. Aspnes et al, Journal of the ACM (JACM), Volume 44, Issue 3 (May 1997).

In other embodiments, the allocation approaches described above may be used with a Mini Fiber Node (mFN). The mFN currently has a small number of sub-channels (initially only two). It serves a small community of users that are expected to have large bandwidth demands. Under these embodiments, the users will be SVC (i.e. will be able to receive two channels each). The system will preferably have:

SVC users who can use two sub-channels from the mFN. If there are more than two sub-channels in the mFN than the above proposed staggered or balanced allocation approaches may be used.

SVC users who can use one mFN channel and one spill-off channel from the headend. This spill-off channel goes to the communities served by multiple mFNs (erg. to the entire city).

Thus, a method and system is provided for digital communications over a fragmented channel are provide, of which several embodiments are described above. While the invention has been described with reference to illustrative embodiments, this description is not intended to be construed in a limiting sense. Various other embodiments of the invention will be apparent to persons skilled in the art upon reference to this description, examples of which have been discussed above.

It is therefore contemplated that the appended claims will cover any such modifications of the embodiments as fall within the true scope and spirit of the invention.

APPENDIX
MATLAB simulation.

function [P_loss,rate] = spill_over(method, N, Nlast)
% [P_loss,rate] = spill_over(methods, Nbalanced, Nlast)
% method: 1=slotted, 2=channel pairs, 3=spill over, 4=iterative, 5=optimal
% N = number of users per channel
% Nlast = number of users in last channel
%%%%%%%%%%%%%%%%%%%%%%%%%%%%%%%%%%%%%%%%%%%%%
%
% 27-10-2000 written by Ofir
% tests ideas for advanced MAC to improve system capacity
%
% results
% K=20; M=15; p=1/2; trial_num = 400; Nlast=20
% * Regular algorithm (method=1)

| | | | | |
|---|---|---|---|---|
| %N= | 20 | 21 | 22 | 24 |
| % P_loss | .0008 | .0016 | .0031 | .01 |
| % rate | 9.97 | 10.46 | 10.97 | 11.84 |

% * Two channels (method=2)

| | | | | | | | |
|---|---|---|---|---|---|---|---|
| % N | 22 | 23 | 24 | 25 | 26 | 27 | 28 |
| % P_loss | 3e−4 | .0011 | .0026 | .005 | .009 | .015 | .026 |

% * Non Iterative Spill Over algorithm (method=3, Nlast=20)

| | | | | |
|---|---|---|---|---|
| % N | 27 | 28 | 29 | 30 |
| % P_loss | .00045 | .0014 | .005 | .014 |
| % rate | 13.3 | 13.79 | 14.2 | 14.52 |

% * Optimal (method==5) - Any request can be served by any channel

| | | | | |
|---|---|---|---|---|
| % N | 28 | 29 | 30 | 31 |
| % P_loss | 7e−4 | .005 | .0167 | .04 |
| % rate | 14 | 14.4 | 14.75 | 14.9 |
| % | | | | |

% conclusions:
% 1. Spill Over is better than conventional by 30% in throughput (or
% number of users) per given loss rate, at least with small M, such as M=15.
% 2. Spill over algorithm is pretty near the optimal algorithm, at
% least with large K, such as K=20.
% 3. Dual channel is better than single channel by 10% in number of users per similar loss rate.
%
% Nlast=20 is not optimal. Trying to optimize it, I gained less than 1% in rate.
%
% With M=60 (p=1/2,K=20) the improvements of methods 2 and 3 over the
% conventional one were only 5% and 11% respectively (at P_loss=.005)
%
%%%%%%%%%%%%%%%%%%%%%%%%%%%%%%%%%%%%%%%%%%%%%%
K = 20; % number of channels <==SHOULD BE EVEN IF METHOD 2 IS USED
M = 60 ; % number of slots that a channel can serve
p = 1/2; % probability that a user needs a slot
if((method==1) | ((method==2)) & ˜(Nlast==N)

error = ‘Nlast should be equal to N’

end
% N = 17; % number of users per channel in the conventional system
% Nbalanced = 30; % number of users in channels 1:K-1 in the balanced system
% Nlast = 5; % number of users in channel K in the balanced system
trial_num = 400;
tx = 0; optimal_tx = 0; last_tx = 0; % reset transmission counters
loss = zeros(1,trial_num);
% slotted approach
for trial=1:trial_num;

% simulate random slot requests
req = [sum( rand(N,K−1)<p ) sum(rand(Nlast,1)<p)];
% optimal performance bound (assuming all channels are a single channel
optimal_tx=optimal_tx+min(M*K,sum(req));
optimal_loss(trial) = max(0,sum(req)-M*K);

if method==1

% simulate regular (slotted) algorithm
loss(trial) = sum( max(0,req-M));
tx = tx + sum( min(M,req));

end
if method==2

% simulate regular (slotted) algorithm with channel pairs
req = req(1:2:K)+req(2:2:K);
loss(trial) = sum( max(0,req-2*M));
tx = tx + sum( min(2*M,reg);

end
if method==3

% simulate spill over algorithm (sub optimal)
for k=1:K−1

loss(trial) = loss(trial) + max(0, req(k) - 2*M);
tx = tx + min(M, req(k));
req(k+1) = req(k+1) + min(max(0,req(k) - M),M);

end
% process last channel
empty_slots_chan1 = max(0,M-req(:));
loss(trial) = loss(trial) + max( 0, req(K)-M-empty_slots_chan1);
tx = tx + min( M+empty_slots_chan1, req(K) );
ttt(trial) = max( 0, req(K) - M - empty_slots_chan1);
last_tx = last_tx + min( M+empty_slots_chan1, req(K) );

```
  end
end % for trial
if method==5
  tx: = optimal_tx; loss = optimal_loss;
end
% show results
P_loss = sum(loss)/tx  % loss probability
rate = tx/K/trial_num  % average data rate per channel
optimal_P_loss = sum(optimal_loss)/tx  % loss probability
optimal_rate = optimal_tx/K/trial_num  % average data rate per channel
if method==3
```

P_last_loss = sum( ttt )/last_tx

end
end

We claim:

1. A data communication system with a transmission channel having transmission sub-channels for transmitting and receiving data, said system comprising:
a first terminal for transmission of data on one or more of a first plurality of sub-channels;
a second terminal for transmission of data on one or more of a second plurality of sub-channels wherein the first plurality of sub-channels and the second plurality of sub-channels are partially overlapping such that at least one sub-channel is shared by the first terminal and the second terminal and at least one sub-channel is not shared by the first terminal and the second terminal; and
a control mechanism for allocating data transmission for the first terminal to one or more of the first plurality of sub-channels and allocating data transmission for the second terminal to one or more of the second plurality of sub-channels.

2. A method of data transmission in a communication system with a transmission channel having transmission sub-channels for transmitting and receiving data, said method comprising:
allocating two or more first sub-channels to a first terminal wherein one of the first sub-channels is a first primary sub-channel and another one of the first sub-channels is a first secondary sub-channel;
allocating one or more second sub-channels to a second terminal wherein one of the second sub-channels is the same sub-channel as the first secondary sub-channel and none of the second sub-channels are the same sub-channel as the first primary sub-channel;
determining if the first primary sub-channel is congested;
transmitting the data from or receiving the data at the first terminal on the first primary sub-channel if the first primary sub-channel is not congested;
requesting to send data on the first secondary sub-channel if the first primary sub-channel is congested;
receiving confirmation that the data may be sent on the first secondary sub-channel; and
transmitting the data from or receiving the data at the first terminal on the first secondary sub-channel.
